(19) United States
(12) Patent Application Publication
(10) Pub. No.: US 2021/0109612 A1
(43) Pub. Date: Apr. 15, 2021

(54) COMPOSITE TOUCHSCREEN DISPLAY

(71) Applicant: Hyperion Motors, Inc., Orange, CA (US)

(72) Inventor: Constantine E. Kafantaris, Orange, CA (US)

(73) Assignee: Hyperion Motors, Inc., Orange, CA (US)

(21) Appl. No.: 16/600,446

(22) Filed: Oct. 11, 2019

(51) Int. Cl. G06F 3/044; G06F 3/042; H05K 1/11; F21V 8/00

(52) U.S. Cl. CPC G06F 3/044; G02B 6/0078; H05K 1/118; G06F 3/0421

(57) ABSTRACT

The present invention provides a composite touch screen display configured to produce an image on a contoured surface without warping. This is accomplished through a display configured to produce an image, a fiber optic panel configured to project the image produced by the display, a touch screen, and a frame configured to retain all of the above components. These components work in conjunction to project the light of the image through a fiber optic panel onto a contoured surface, while maintaining the proportions of the image after projection.

### CROSS-REFERENCE TO RELATED APPLICATIONS

Not Applicable.

### STATEMENT REGARDING FEDERALLY SPONSORED RESEARCH AND DEVELOPMENT

Not Applicable.

### FIELD OF THE INVENTION

This invention relates to a composite touchscreen display, and more particularly, to an apparatus for projecting an image from a display onto a contoured surface while maintaining the original proportions of the image.

### DISCUSSION OF RELATED ART

An optical fiber cable can generally be described as a cable that can carry light from one end to another. Optical fiber cables comprise one or more optical fibers, which are individually coated with a material that will internally reflect light. As such, the light will travel within the optical fibers and reflect inward until they reach their destination. Optical fiber cables are often used for data communications, where data can travel at extremely high speeds and over long distances without data loss.

A display can generally be described as a device for visually representing data. Displays are traditionally flat and comprise a plurality of pixels, wherein each pixel is adapted to display a light, and wherein the plurality of pixels and lights form an image. The amount and orientation of the pixels is represented by a resolution, with higher resolutions corresponding to smaller and more densely-packed pixels within the display. Common displays include LCD displays, LED displays, plasma displays, and CRT displays.

While various displays exist in the prior art, they are traditionally limited to flat panel displays having limited curves and little to no contours. Furthermore, although display technology is advancing quickly, with folding screens becoming more prevalent, there are still limited options for curved screen technology, especially where a robust and durable contoured surface is used with touch. As such, there is a continued need for a composite touch screen display configured to project an image on a contoured surface without warping. The present invention satisfies these needs.

### SUMMARY OF THE INVENTION

The present invention provides a composite touch screen display configured to project an image on a contoured surface without warping. This is accomplished through a display configured to produce an image, a fiber optic panel configured to project the image produced by the display, a touch screen, and a frame configured to retain all of the above components. These components work in conjunction to project the light of the image through a fiber optic panel onto a contoured surface, while maintaining the proportions of the image after projection.

These and other objectives of the present invention will become obvious to those of ordinary skill in the art after reading the following detailed description of the preferred embodiments. It is to be understood that the foregoing general description and the following detailed description are exemplary, and are intended to provide further explanation of the invention as claimed.

### DESCRIPTION OF THE DRAWINGS

FIG. 1 is a front perspective view of the composite touchscreen display according to one embodiment of the present invention;

FIG. 2 is a side view therein;

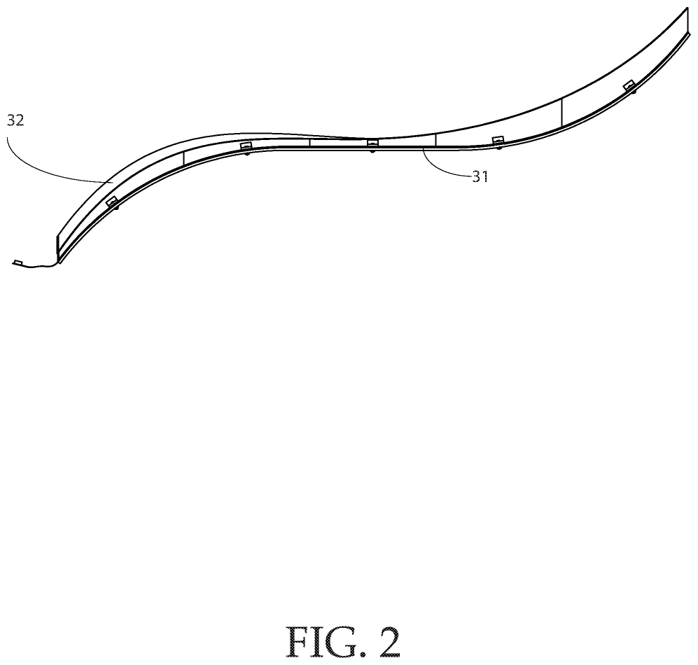

FIG. 3 is a front view therein;

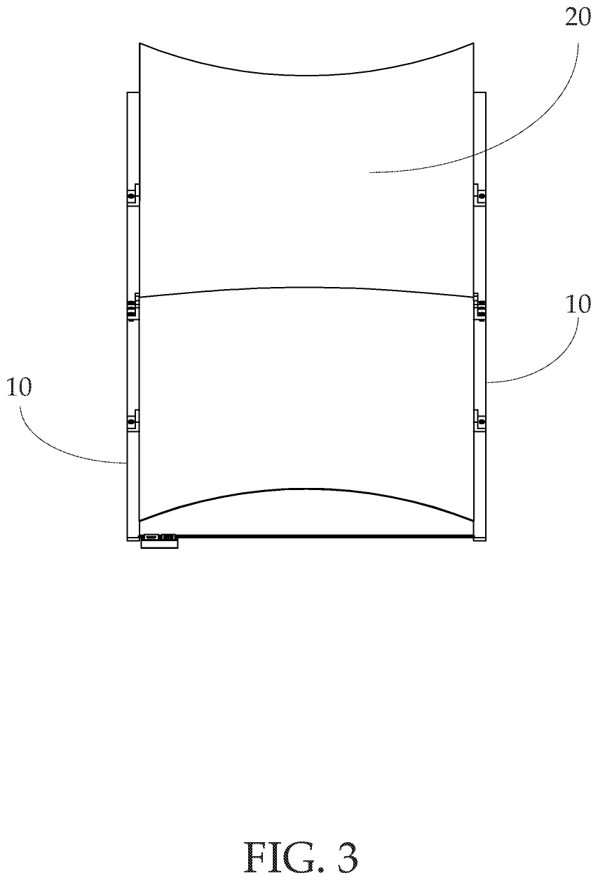

FIG. 4 is a front perspective exploded view therein;

FIG. 5 is a front perspective exploded view therein showing a plurality of fiber optic panels;

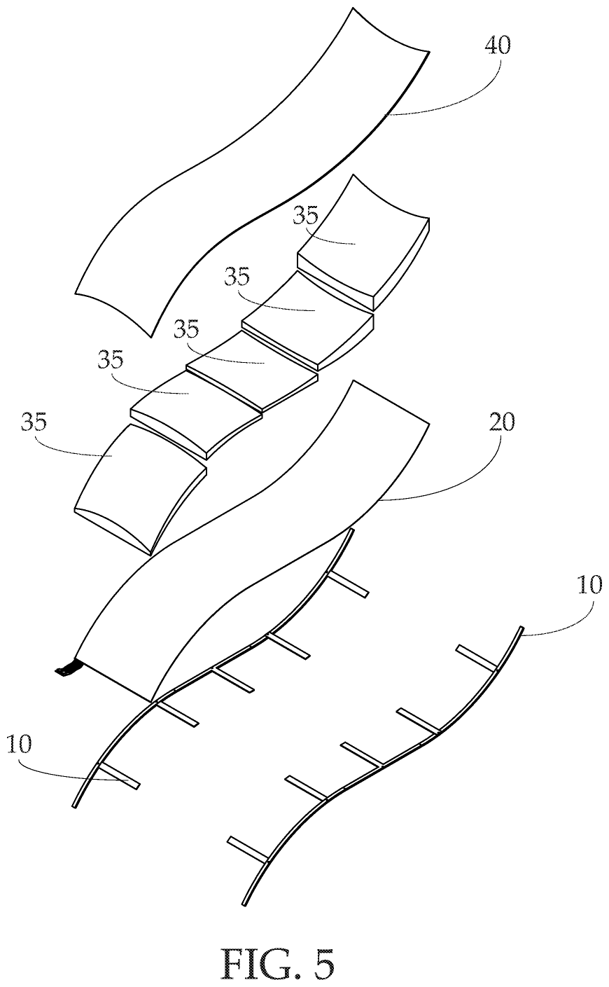

FIG. 6 is a perspective view of the composite touchscreen display with a distorted image of a grid displayed on the fiber optic display;

FIG. 7 is a top view of an image of a grid displayed on the display;

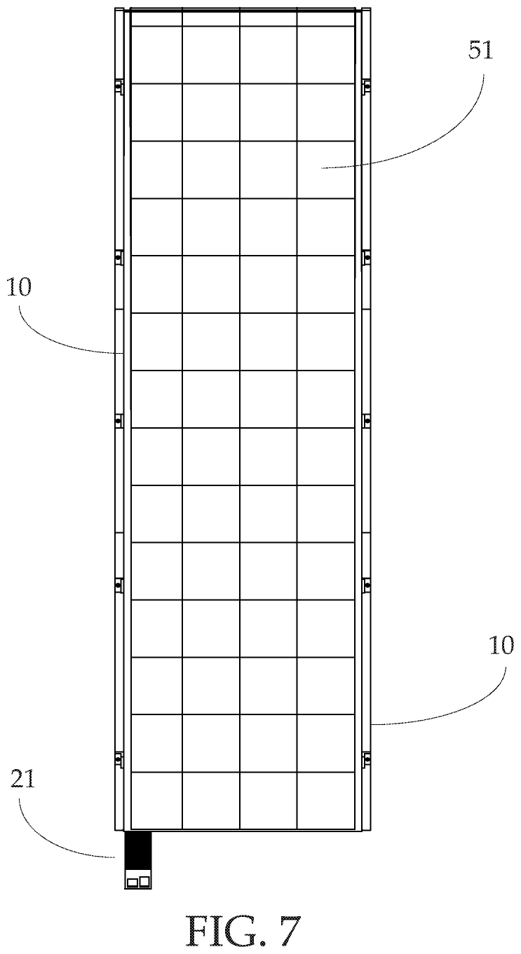

FIG. 8 is a front perspective exploded view of the display and fiber optic panel, wherein an image of a grid is displayed on the display, and wherein the image of a grid is not distorted when viewed from the fiber optic display; and

FIG. 9 is a front perspective tear-away view of the fiber optic panel showing the fiber optic channels.

### DETAILED DESCRIPTION OF THE PREFERRED EMBODIMENT

Illustrative embodiments of the invention are described below. The following explanation provides specific details for a thorough understanding of and enabling description for these embodiments. One skilled in the art will understand that the invention may be practiced without such details. In other instances, well-known structures and functions have not been shown or described in detail to avoid unnecessarily obscuring the description of the embodiments.

Unless the context clearly requires otherwise, throughout the description and the claims, the words “comprise,” “comprising,” and the like are to be construed in an inclusive sense as opposed to an exclusive or exhaustive sense; that is to say, in the sense of “including, but not limited to.” Words using the singular or plural number also include the plural or singular number respectively. Additionally, the words “herein,” “above,” “below” and words of similar import, when used in this application, shall refer to this application as a whole and not to any particular portions of this application. When the claims use the word “or” in reference to a list of two or more items, that word covers all of the following interpretations of the word: any of the items in the list, all of the items in the list and any combination of the items in the list.

The composite touchscreen display comprises a display 20 configured to produce an image on a contoured surface, a fiber optic panel 30 configured to project the image produced by the display 20, a touch screen 40, and a frame 10 configured to retain all of the above components. These components work in conjunction to project an image from a display through a fiber optic panel having a contoured surface, while maintaining visibility of the image after projection.

The fiber optic panel 30 comprises a proximal surface 31 and a distal surface 32. The proximal surface 31 is flat and positioned adjacent to the display 20, while the distal surface 32 is positioned on the opposing side of the proximal surface 31. The distal surface 32 further comprises a contoured surface, where the contoured surface is different in shape than the proximal surface 31. The fiber optic panel 30 is configured to receive images from the display 20 at the proximal surface 31 and project the image to the distal surface 32. The properties of the fiber optic panel 30 can be customized depending on the needs of the user. Fiber optic panel 30 properties include contoured surface shape, fiber optic panel thickness, and desired viewing angle.

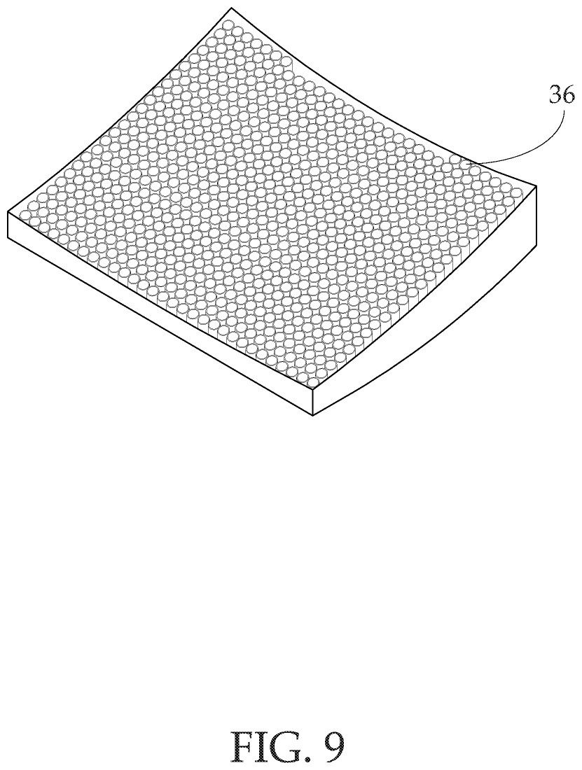

The fiber optic panel 30 further comprises a plurality of fiber optic channels 36 (FIG. 9) positioned adjacent to one another and perpendicular to the proximal and distal surfaces 31, 32. The plurality of fiber optic channels 36 further comprise proximal and distal ends, wherein the proximal ends form the proximal surface 31 of the fiber optic panel 30, and wherein the distal ends form the distal surface 32 of the fiber optic panel 30. The fiber optic channels 36 are configured to transmit light from their proximal end to their distal end, and as such, will facilitate the transfer of light from the proximal surface 31 to the distal surface 32 of the fiber optic panel 30. The density of the fiber optic channels 36 contained within the fiber optic panel 30 may vary depending on the needs of the user. In an alternative embodiment, the fiber optic channels 36 are one-way fiber optic channels, where light can travel from the proximal side to the distal side, but cannot travel from the distal side to the proximal side.

In an alternative embodiment, the fiber optic panel 30 comprises a plurality of fiber optic sections 35 positioned adjacent to one another such that, when combined, form a fiber optic panel 30 having the same properties as described above. More specifically, instead of having a single fiber optic panel 30, a plurality of fiber optic sections 35 are used such that, when they are combined, operate identically to the fiber optic panel 30. When the fiber optic panels 35 are positioned correctly, they create unified proximal and distal surfaces 31, 32. Fiber optic sections 35 may be used due lower construction costs, reduce repair costs, reduce installation costs, increase compatibility, or otherwise overcome practical limitations of the environment where the present invention will be implemented.

The display 20 is configured to produce an image. More specifically, the display 20 comprises a plurality of light sources which produce a plurality of lights that, when viewed together, form said image. In the preferred embodiment, the display 20 is flat and positioned adjacent to the proximal surface 31 of the fiber optic panel 30. The display 20 produces the image and the fiber optic channels 36, positioned adjacent to the display 20, receive the light of said image and project the light from the proximal surface 31 to the distal surface 32. When the image is projected from a flat, proximal surface 31 to a contoured, distal surface 32, the image may appear warped or otherwise disproportionate to the original image, depending on the shape of the contoured surface.

In an alternative embodiment, the display 20 further comprises a processor configured to distort the image to counteract the expansion and contraction that may be caused by projecting the image onto a contoured surface 32. More specifically, when the image is projected onto a contoured surface 32, it will appear warped and disproportionate. The processor will apply distortion to the image such that the original proportions of the image appear normal when viewed from the contoured surface 32. In a further alternative embodiment, the display 20 comprises a frame buffer holding all output images in sequence, wherein the processor will distort the image by applying an output filter to the frame buffer, wherein the output filter will apply the same distortion to every output image in the frame buffer, and consequently, every image produced by the display 20. An output filter will reduce the complexity of producing an accurate image on the distal surface 32, as the contoured surface has a fixed shape and any distortion will only need to counter the fixed shape of this contoured surface. In a further alternative embodiment, the display further comprises a dynamic output filter, where a plurality of filters are applied to said image depending on a desired viewing angle or to produce a desired visual effect on the contoured surface.

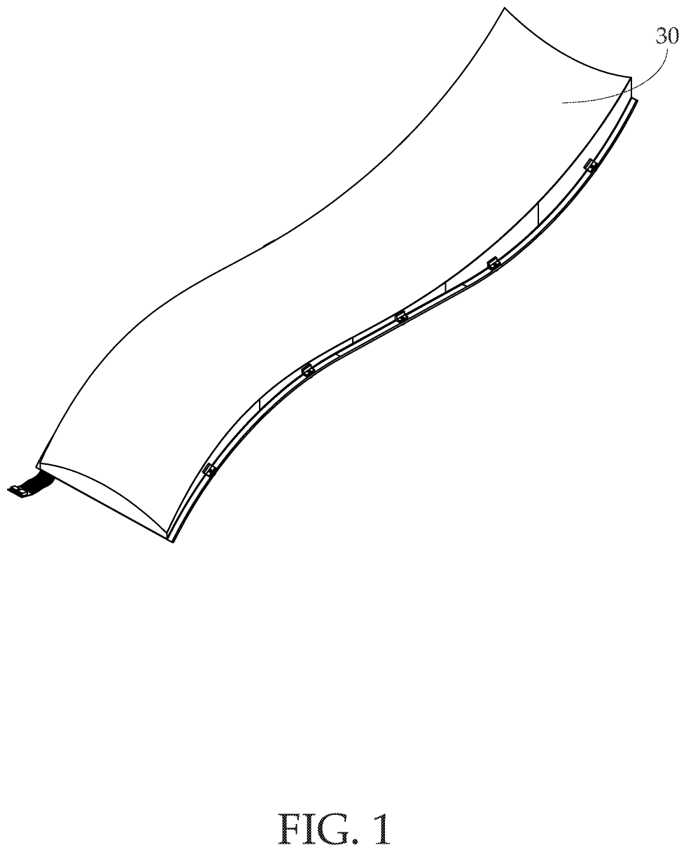

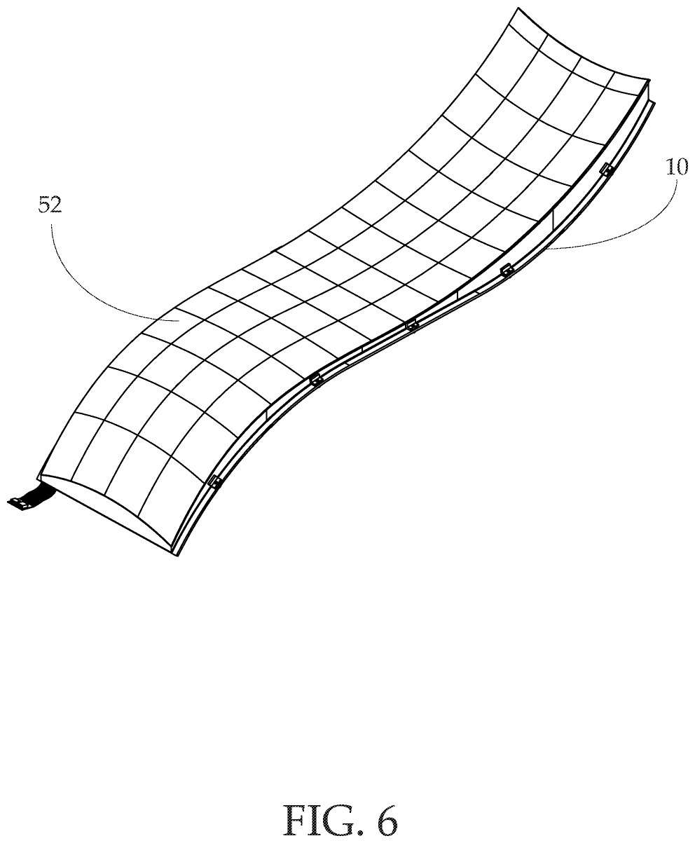

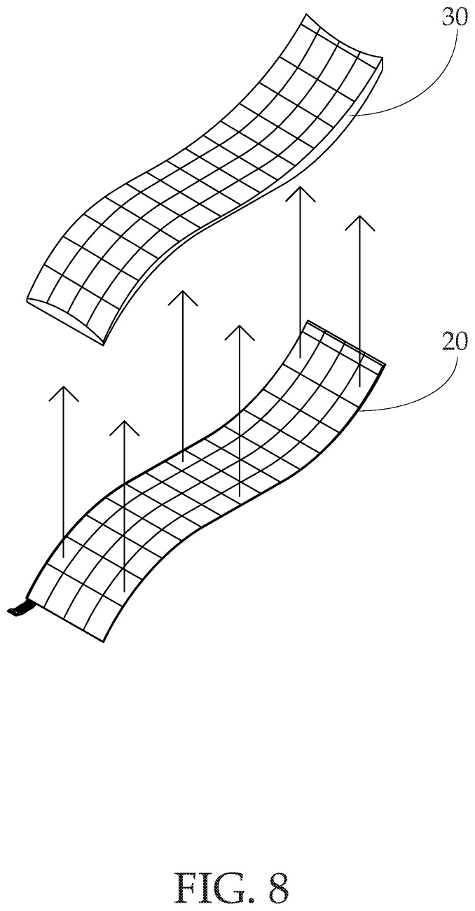

The distortion produced by the processor will vary depending on the shape of the contoured surface 32 used and the optimal viewing angle. For example, if the contoured surface 32 has a curve as shown in FIG. 1, with an concave curve at the top and a convex curve at the bottom, then the display will distort the images to accommodate for the curvature at the top and bottom of the image such that the image, when viewed from the distal surface 32 of the fiber optic panel 30, will not seem warped or otherwise abnormal. In an exemplary embodiment, shown in FIG. 8, an un-distorted image of a grid 51 is shown on the display 20 and on the fiber optic panel 30. A warped image of a projected grid is shown when viewed on the distal side 32 of the fiber optic panel 30 without any distortion. When the image of a grid is projected and distorted 52, as shown in FIG. 6, the image will be represented on the distal side 32 of the fiber optic display 30 with the original proportions and accommodating the contoured surface 32 of the fiber optic display 30.

The touch screen 40 comprises a device configured to receive touch input. Touch input comprises input from touch (fingers, stylus, gloves, etc.) and will accommodate single and multi-touch gestures. Common touch gestures include selecting objects, scrolling, highlighting text, pinching to zoom, and other gestures for navigating a user interface. The touch screen 40 is positioned adjacent to the fiber optic panel 30 at the distal end 32 and shares the shape of the contoured surface 32. In an alternative embodiment, the touch screen 40 is a capacitive touch screen.

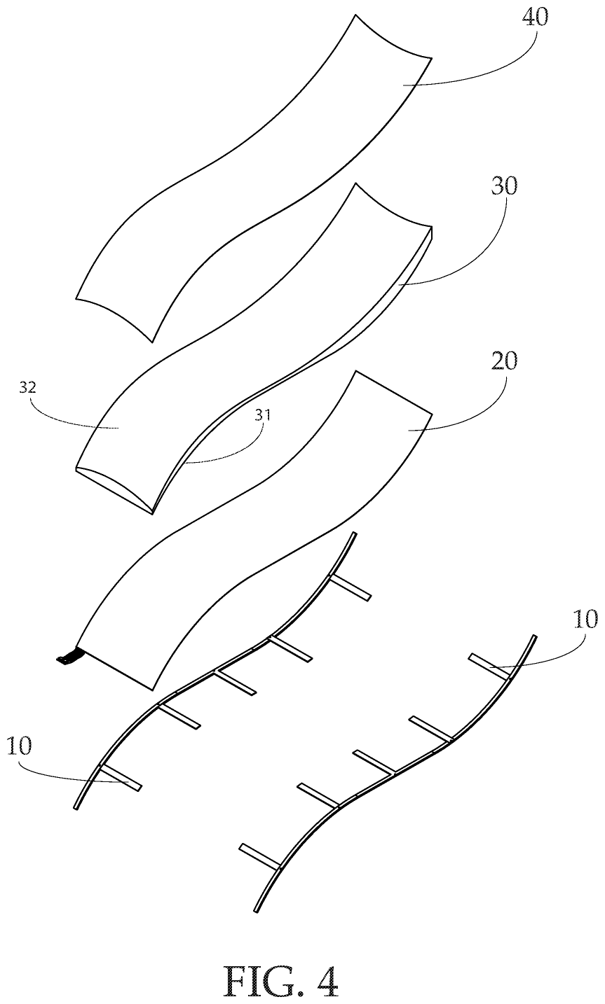

The frame 10 comprises a structural element configured to retain all of the above-mentioned components. The frame 10 is illustrated in FIG. 4 in an exploded view, with opposing frame members further comprise a plurality of frame supports positioned perpendicular to the opposing frame members. When combined, the frame supports will join and provide structural support for the device. Although the frame 10 shown in FIG. 4 and described above is an exemplary embodiment, any shape can be used for the frame 10 so long as it adequately supports the components of the present invention.

While the above description contains specific details regarding certain elements, sizes, and other teachings, it is understood that embodiments of the invention or any combination of them may be practiced without these specific details. Specifically, although certain shapes are described and shown in the above embodiments and drawings, any suitable shape may be used. These details should not be construed as limitations on the scope of any embodiment, but merely as exemplifications of the presently preferred embodiments. In other instances, well known structures, elements, and techniques have not been shown to clearly explain the details of the invention.

The above detailed description of the embodiments of the invention is not intended to be exhaustive or to limit the invention to the precise form disclosed above or to the particular field of usage mentioned in this disclosure. While specific embodiments of, and examples for, the invention are described above for illustrative purposes, various equivalent modifications are possible within the scope of the invention, as those skilled in the relevant art will recognize. Also, the teachings of the invention provided herein can be applied to other systems, not necessarily the system described above. The elements and acts of the various embodiments described above can be combined to provide further embodiments.

Changes can be made to the invention in light of the above “Detailed Description.” While the above description details certain embodiments of the invention and describes the best mode contemplated, no matter how detailed the above appears in text, the invention can be practiced in many ways. Therefore, implementation details may vary considerably while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated.

While certain aspects of the invention are presented below in certain claim forms, the inventor contemplates the various aspects of the invention in any number of claim forms. Accordingly, the inventor reserves the right to add additional claims after filing the application to pursue such additional claim forms for other aspects of the invention.

What is claimed is:

1. A composite touchscreen display comprising:
a display configured to produce an image; and
a fiber optic panel comprising a proximal surface and a distal surface, said proximal surface positioned adjacent to said display, said distal surface further comprising a contoured surface;
wherein said fiber optic panel is configured to receive said image from said display at said proximal surface and project said image to said distal surface.

2. The composite touchscreen display of claim 1, wherein said fiber optic panel further comprises a plurality of fiber optic channels positioned between said proximal surface and said distal surface, wherein said fiber optic channels are configured to transmit light from said proximal surface to said distal surface.

3. The composite touchscreen display of claim 1, wherein said fiber optic panel further comprises a plurality of fiber optic sections positioned adjacent to one another, said plurality of fiber optic sections forming unified proximal and distal surfaces.

4. The composite touchscreen display of claim 1, wherein said proximal surface is flat and wherein said distal surface is different in shape than said proximal surface.

5. The composite touchscreen display of claim 1, wherein said display further comprises a processor configured to distort said image.

6. The composite touchscreen display of claim 5, wherein said distortion further comprises modifying said image such that said image will maintain the original proportions and not appear warped or abnormal when viewed from said contoured surface of said fiber optic panel.

7. The composite touchscreen display of claim 6, wherein said display further comprises:
a frame buffer holding all output images, and
an output filter configured to apply the same distortion to every output image in said frame buffer;
wherein said processor will distort said image by applying said output filter to said frame buffer, thereby uniformly distorting every image produced by the display.

8. The composite touchscreen display of claim 1, further comprising a touch screen positioned adjacent to said fiber optic panel at said distal end, said touch screen configured to receive touch input.

9. The composite touchscreen display of claim 8, wherein said touch screen further comprises a capacitive touch screen.

10. The composite touchscreen display of claim 1, further comprising a frame configured to retain the display, fiber optic panel, and touch screen.
